(19) United States
(12) Patent Application Publication
(10) Pub. No.: US 2015/0070681 A1
(43) Pub. Date: Mar. 12, 2015

(54) PATTERN GENERATING METHOD, PATTERN FORMING METHOD, AND PATTERN GENERATING PROGRAM

(71) Applicant: Kabushiki Kaisha Toshiba, Minato-ku (JP)

(72) Inventors: Taiga Uno, Yokohama-shi (JP); Takaki Hashimoto, Yokohama-shi (JP)

(73) Assignee: Kabushiki Kaisha Toshiba, Minato-ku (JP)

(21) Appl. No.: 14/187,590

(22) Filed: Feb. 24, 2014

Related U.S. Application Data
(60) Provisional application No. 61/876,306, filed on Sep. 11, 2013.

(51) Int. Cl. G03F 7/20

(52) U.S. Cl. CPC G03F 7/70066
USPC 355/77

(57) ABSTRACT

In general, according to one embodiment, a pattern generating method evaluates an amount of flare generated through a mask during an EUV exposure; calculates optimal coverage of a mask pattern for enhancing uniformity of the amount of flare in an exposure region by applying an optimization algorithm; and generates a dummy pattern of the mask based upon the coverage of the mask pattern.

### CROSS-REFERENCE TO RELATED APPLICATIONS

This application is based upon and claims the benefit of priority from Provisional Patent Application No. 61/876,306, filed on Sep. 11, 2013; the entire contents of which are incorporated herein by reference.

### FIELD

Embodiments described herein relate generally to a pattern generating method, a pattern forming method, and a pattern generating program.

### BACKGROUND

A lithography technique using an EUV (Extreme Ultra Violet) light source has been developed to achieve microfabrication and high integration of a semiconductor device. In the lithography using the EUV light source, scattering on an optical reduction system of an exposure device increases, since a wavelength of the EUV light source is smaller than a wavelength of ArF. The scattering light (flare) leaks from an open portion on a mask pattern, and varies a size of a resist pattern formed on a substrate in some cases. In order to reduce the influence of the flare, a method of achieving uniform flare intensity by an arrangement of a dummy pattern around the mask pattern has sometimes been used.

### BRIEF DESCRIPTION OF THE DRAWINGS

FIG. 1 is a block diagram illustrating a schematic configuration of a pattern generating system according to a first embodiment;

FIGS. 2(a) and 2(b) are sectional views illustrating a change in a flare amount according to a mask opening coverage according to the first embodiment;

FIG. 3 is a sectional view illustrating a change in a method of calculating a flare amount using a point spread function according to the first embodiment;

FIG. 4 is a sectional view illustrating a method of adjusting the flare amount according to the first embodiment;

FIG. 5(a) is a plan view illustrating an example of a layout of a mask pattern according to the first embodiment, FIG. 5(b) is a plan view illustrating a density map in each mesh region to the layout in FIG. 5(a), FIG. 5(c) is a view illustrating a flare distribution according to each mesh region in FIG. 5(b), and FIG. 5(d) is a view illustrating a flare distribution to the layout in FIG. 5(a), the distribution being obtained by convolution integral to the flare distribution according to each mesh region in FIG. 5(c);

FIG. 6 is a view illustrating a method of adjusting a density map by Newton method in order to equalize the flare distribution according to the first embodiment;

FIG. 7 is a flowchart illustrating the method of adjusting the density map for equalizing the flare distribution according to the first embodiment;

FIG. 8 is a view illustrating an approximating method of a density map according to a second embodiment;

FIG. 9 is a flowchart illustrating a method of adjusting the density map for equalizing the flare distribution according to the second embodiment;

FIG. 10 is a block diagram illustrating an example of a configuration of hardware in the pattern generating device in FIG. 1; and

FIG. 11 is a perspective view illustrating a schematic configuration of an EUV exposure device to which an exposure mask according to a third embodiment is applied.

### DETAILED DESCRIPTION

In general, according to one embodiment, a pattern generating method evaluates an amount of flare generated through a mask during an EUV exposure; calculates coverage of a mask pattern for enhancing uniformity of the amount of flare in an exposure region by applying an optimization algorithm; and generates a dummy pattern of the mask based upon the coverage of the mask pattern.

Exemplary embodiments of the pattern generating method will be explained below in detail with reference to the accompanying drawings. The present invention is not limited to the following embodiments.

### First Embodiment

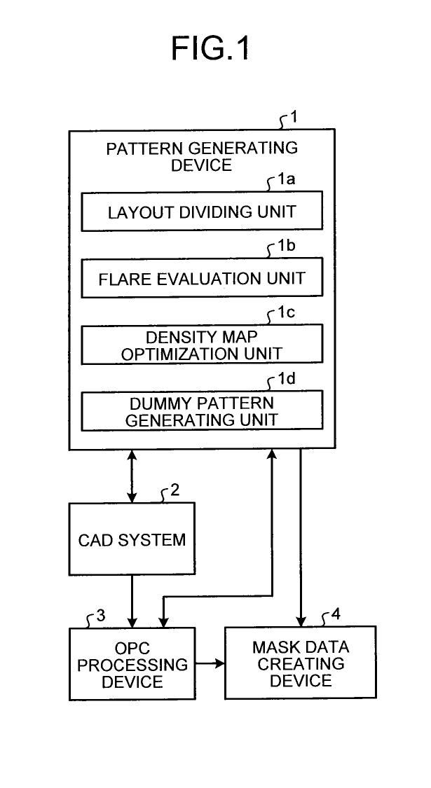

FIG. 1 is a block diagram illustrating a schematic configuration of a pattern generating system according to a first embodiment.

In FIG. 1, a pattern generating system includes a pattern generating device 1, a CAD system 2, an OPC (Optical Proximity Correction) processing device 3, and a mask data creating device 4. The pattern generating device 1 includes a layout dividing unit 1a, a flare evaluation unit 1b, a density map optimization unit 1c, and a dummy pattern generating unit 1d.

The CAD system 2 can create design layout data corresponding to a layout pattern of each layer in a semiconductor integrated circuit. Examples of a data format of the design layout data include text coordinate data, GDS data, and OASIS data.

The OPC processing device 3 can perform optical proximity correction to the layout pattern specified by the design layout data created by the CAD system 2 or the pattern generating device 1. The mask data creating device 4 can create mask data corresponding to the design layout data to which the optical proximity correction and the dummy pattern generation are performed.

The pattern generating device 1 calculates coverage of a mask pattern by applying an optimization algorithm for enhancing uniformity of the amount of flare in an exposure region, and generates a dummy pattern of the mask based upon the coverage. The layout dividing unit 1a can divide the layout region of the mask pattern. In this case, the layout dividing unit 1a can divide the layout region of the mask pattern in a mesh with a predetermined space. The way of dividing the layout region is not limited to the mesh, and any size and any shape can be set. The flare evaluation unit 1b can evaluate the amount of generated flare through the mask during the EUV exposure. The flare evaluation unit 1b obtains a density of the pattern for each of the divided regions divided by the layout dividing unit 1a, and can evaluate the amount of flare in the exposure region based upon a convolution integral with a point spread function. The density map optimization unit 1c can calculate the coverage of the mask pattern by applying the optimization algorithm for enhancing the uniformity of the amount of flare in the exposure region. It is to be noted that the coverage is sometimes referred to as a density. The density distribution of the mask pattern of the mask is sometimes referred to as a density map. The intensity distribution of flare in the exposure region is sometimes referred to as a flare map. A gradient method such as Newton method can be used as the optimization algorithm, for example. A quasi-Newton method may be used. Alternatively, linear programming or genetic algorithm may be used. The dummy pattern generating unit 1d can generate dummy patterns of the mask based upon the coverage of the mask pattern calculated by the density map optimization unit 1c.

The CAD system 2 creates design layout data corresponding to a layout pattern of each layer in a semiconductor integrated circuit, and sends the created data to the OPC processing device 3. The CAD system 2 can add or replace the dummy patterns generated manually or by the pattern generating device 1. The OPC processing device 3 performs the optical proximity correction to the layout pattern obtained from the design layout data created by the CAD system 2, and sends the resultant to the pattern generating device 1 or the mask data creating device 4. When the OPC processing device 3 performs the optical proximity correction, the design layout data can be corrected such that the dimensional difference between the size obtained by the exposure simulation and the layout pattern obtained from the design layout data is minimized.

When the layout data is inputted to the pattern generating device 1, the layout dividing unit 1a divides the layout region of the mask pattern corresponding to the design layout data. The flare evaluation unit 1b then evaluates the amount of flare emitted on the exposure region through the mask on which the mask pattern is formed. In this case, the amount of flare may be evaluated only in the region where the uniformity of the amount of flare has to be enhanced. The density map optimization unit 1c calculates the coverage of the mask pattern for enhancing the uniformity of the amount of flare in the exposure region by applying the optimization algorithm. In this case, the density map optimization unit 1c can obtain an amount of change in the variation of the flare amount when the coverage is changed for each of the divided regions divided by the layout dividing unit 1a by the optimization method such as the gradient method, and can calculate the coverage in order that the variation in the flare amount becomes close to the minimum value. The coverage may be changed only in the region where the dummy pattern can be arranged. Alternatively, the coverage of the mask pattern may be approximated by a polynomial equation, a coefficient of the polynomial equation may be calculated by using the optimization method such as the gradient method for enhancing the uniformity of the flare amount in the exposure region, and the coverage may be calculated from the polynomial equation.

Examples of the optimization method include a downhill simplex method (Polytope), a genetic algorithm, and simulated annealing, in addition to the gradient method (Newton method, quasi-Newton method, optimal gradient method, and conjugate gradient method). The combination of these optimization methods can be used.

The dummy pattern generating unit 1d generates dummy patterns based upon the coverage of the mask pattern calculated by the density map optimization unit 1c. The mask data creating device 4 adds or replaces the dummy pattern, which is generated by the dummy pattern generating unit 1d, to the mask pattern corresponding to the layout pattern of the semiconductor integrated circuit. Alternatively, the CAD system 2 may add or replace the dummy patterns, and the OPC processing device 3 may perform the OPC process.

Since the coverage of the mask pattern is calculated in order to enhance uniformity of the flare amount in the exposure region based upon the optimization algorithm, the flare amount in the exposure region can systematically be equalized, and the dummy pattern can effectively be added without relying on intuition and level of skill of a designer.

Since the coverage of the mask pattern is approximated by a polynomial equation, a coefficient of the polynomial equation is calculated for enhancing the uniformity of the flare amount in the exposure region, and the coverage is calculated from the polynomial equation, design parameters for optimization can be reduced more than in the case where the coverage is optimized by directly changing the coverage. Accordingly, the calculation amount involved with the optimization of the coverage can be reduced.

Since the convolution integral with the point spread function is executed by using not a pattern but a density map to evaluate the flare amount in the exposure region, the calculation amount can be reduced more than in the case where the flare amount is calculated by using a pattern. Accordingly, the calculation of the flare amount can be made with higher speed.

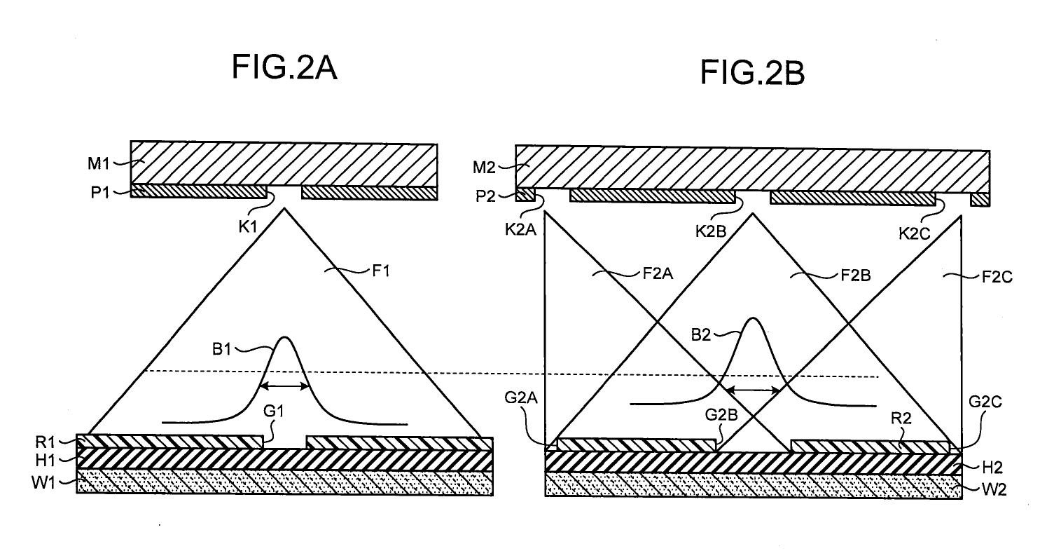

FIGS. 2(a) and 2(b) are sectional views illustrating a change in the flare amount according to a mask opening coverage according to the first embodiment.

In FIG. 2(a), a mask pattern P1 is formed on an exposure mask M1, and an opening K1 is formed on the mask pattern P1. A film to be processed H1 is formed on a wafer W1, and a resist film R1 is formed on the film to be processed H1. The film to be processed H1 may be an insulating film, a metal film, or a semiconductor film. After the resist film R1 is exposed through the exposure mask M1, the resist film R1 is developed, whereby an opening G1 corresponding to the opening K1 is formed on the resist film R1. In this case, flare F1 occurs corresponding to the opening K1. The intensity distribution of the exposure in this case is B1.

On the other hand, in FIG. 2(b), a mask pattern P2 is formed on an exposure mask M2, and openings K2A, K2B, and K2C are formed on the mask pattern P2. A film to be processed H2 is formed on a wafer W2, and a resist film R2 is formed on the film to be processed H2. After the resist film R2 is exposed through the exposure mask M2, the resist film R2 is developed, whereby openings G2A, G2B, and G2C corresponding respectively to the openings K2A, K2B, and K2C are formed on the resist film R2. Flares F2A, F2B, and F2C occur corresponding respectively to the openings K2A, K2B, and K2C in this case. Each of the flares F2A, F2B, and F2C spreads on the resist film R2 over 10 mm. These flares F2A, F2B, and F2C are superimposed, whereby an intensity distribution B2 whose intensity rises more than the intensity of the intensity distribution B1 is formed around the opening G2B. Therefore, even if the size of the opening K1 on the mask pattern and the size of the opening K2B are the same, the flare intensity on the resist film changes according to the coverage of the mask opening on the neighboring mask pattern, resulting in that the finished dimension becomes different. Accordingly, the uniformity of the dimension of the pattern formed on the resist film is deteriorated.

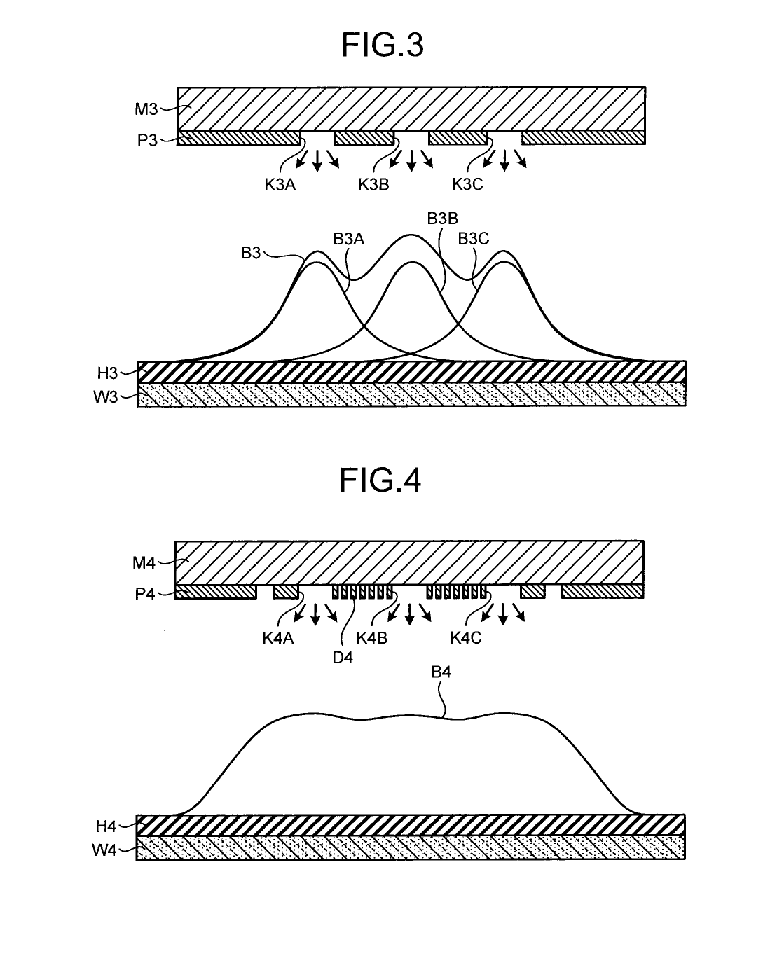

FIG. 3 is a sectional view illustrating a change in a method of calculating a flare amount using a point spread function according to the first embodiment. The flare can be calculated by using distribution, which is called a point spread function, and which indicates the spread of the flare during the exposure of a very small point (hole) pattern.

In FIG. 3, a mask pattern P3 is formed on an exposure mask M3, and openings K3A, K3B, and K3C are formed on the mask pattern P3. A film to be processed H3 is formed on a wafer W3. In this case, flare intensity distributions B3A, B3B, and B3C obtained by multiplying an opening area and a point spread function are generated with respect to the openings K3A, K3B, and K3C. The flare intensity distribution B3 on the film to be processed H3 can be obtained by adding these flare intensity distributions B3A, B3B, and B3C.

FIG. 4 is a sectional view illustrating a method of adjusting the flare amount according to the first embodiment.

In FIG. 4, a mask pattern P4 is formed on an exposure mask M4, and openings K4A, K4B, and K4C as well as a dummy pattern D4 are formed on the mask pattern P4. The size of the dummy pattern D4 can be set to be not more than the resolution limit of the EUV light in order to prevent the dummy pattern D4 from being transferred onto a film to be processed H4. The film to be processed H4 is formed on a wafer W4. In this case, flare is generated corresponding respectively to the openings K4A, K4B, K4C, and the dummy pattern D4. The flare intensity distribution B4 on the film to be processed H4 can be obtained by adding these flare intensity distributions. The flare intensity distribution B4 on the film to be processed H4 can be made uniform by providing the dummy pattern D4 on the exposure mask M4.

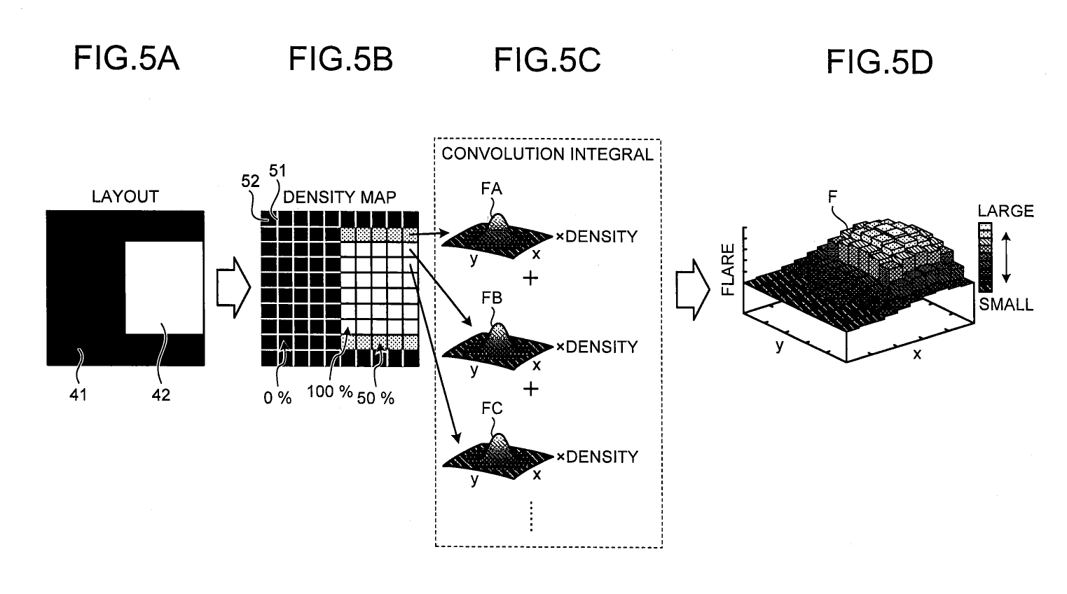

FIG. 5(a) is a plan view illustrating an example of a layout of a mask pattern according to the first embodiment, FIG. 5(b) is a plan view illustrating a density map in each mesh region to the layout in FIG. 5(a), FIG. 5(c) is a view illustrating a flare distribution (distribution obtained by multiplying the point spread function and the density) according to each mesh region in FIG. 5(b), and FIG. 5(d) is a view illustrating a flare distribution, obtained by adding the flare distributions in each of the mesh regions in FIG. 5(c), with respect to the layout in FIG. 5(a). Specifically, the flare map can be obtained by a convolution integral between the density map and the point spread function.

In FIG. 5(a), a layout pattern 42 is formed on a layout region 41 of the mask pattern. As illustrated in FIG. 5(b), a mesh 51 is formed on the layout region 41, and the layout region 41 is divided into divided regions 52 by the mesh 51. Coverage is obtained for each divided region 52. In this case, the coverage in the divided region 52 having no layout pattern 42 is 0%, the coverage of the divided regions 52 covered by the layout pattern 42 is 100%, and the coverage of the divided regions 52 whose center is located on the boundary of the layout pattern 42 is 50%, since the boundary of the layout pattern 42 is located just on the center of each of the divided regions.

As illustrated in FIG. 5(c), point distributions FA, FB, FC . . . are obtained for each of the divided regions 52 based upon the point spread function. The point distribution according to the mesh area for each of the divided regions 52 and the density (FA, FB, FC . . . ) are multiplied, and the products of the multiplication are added, whereby a flare amount F in the exposure region on xy plane can be evaluated as illustrated in FIG. 5(d).

After the flare amount F in the exposure region on the xy plane in FIG. 5(d) is obtained, dummy patterns are given to the layout region 41 in order to make the intensity distribution of the flare amount F uniform. In this case, the coverage of the mask pattern is calculated in order that the uniformity of the flare amount in the exposure region is enhanced based upon the optimization algorithm. The dummy pattern is set to satisfy the coverage of the mask pattern. Newton method can be employed as the optimization algorithm. According to Newton method, the amount of change in the variation of the flare amount F when the coverage is changed for each of the divided regions 52 formed by dividing the layout region 41 is obtained, and the coverage can be calculated repetitively and repeatedly such that the amount of variation of the flare amount becomes close to zero by using the amount of change in the variation of the flare amount F.

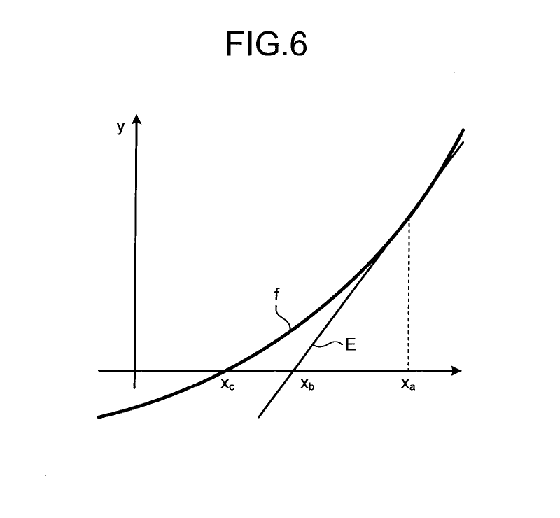

FIG. 6 is a view illustrating a method of adjusting a density map by Newton method in order to equalize the flare distribution according to the first embodiment, wherein only one divided region 52 is present for simplicity's sake. In FIG. 6, an X axis indicates the coverage of the divided region 52, and a Y axis indicates the variation value of the flare amount by the divided region 52.

In FIG. 6, a function y=f(X) of the flare variation is an actual function for each divided region 52. Xa is a current coverage. Xc is the coverage that the variation value of the flare amount is 0. When the point where the tangent E of f(X) at Xₐ intersects with the X axis is specified as X_{b}, X_{b} is a better approximation than Xₐ to the root Xc of f(X)=0. Therefore, it is supposed that the position of X where Y=0 is established with a linear approximate equation is closer to the minimum value of the amount of variation of the flare amount. The equation (1) is repeated to calculate the X position where Y=0 is established.

X=X−f(X)/f′(X) (1)

There are plural (N) divided regions 52 in reality. Therefore, amounts of change in flare variation f′(x1) to f′(xN) are calculated for each of the regions, and simultaneous equation is solved to obtain densities x1 to xN in the respective regions with y=0.

Thus, the flare amount in the exposure region can systematically be equalized, and the dummy pattern can effectively be added without relying on intuition and level of skill of a designer.

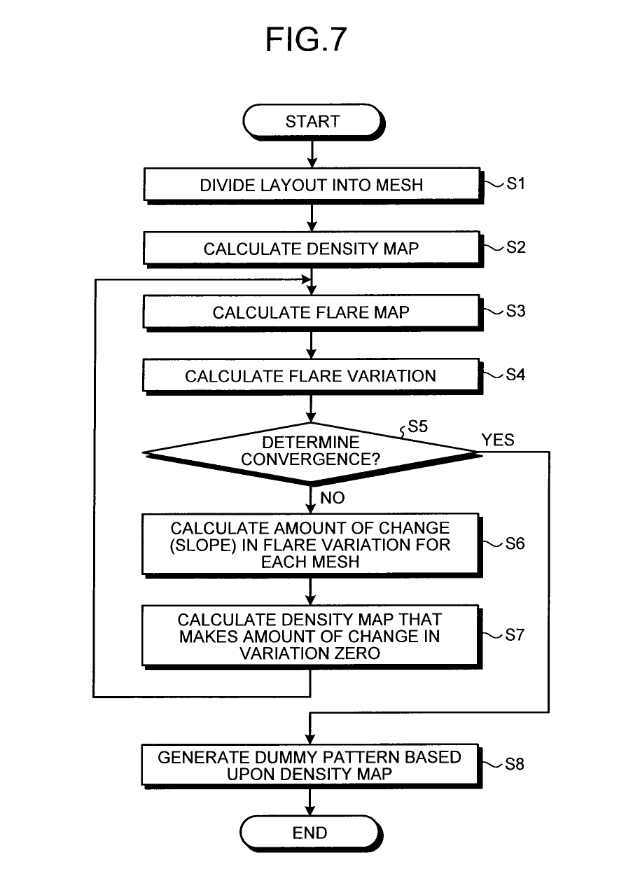

FIG. 7 is a flowchart illustrating the method of adjusting the density map for equalizing the flare distribution according to the first embodiment.

In FIG. 7, the layout region is divided like a mesh (S1). Then, a density map, a flare map, and a flare variation are calculated for each mesh (S2 to S4). The flare variation can be represented by a standard deviation or a range (maximum value−minimum value). The flare map and the flare variation may be calculated only in the region where the uniformity of the flare amount has to be enhanced. It is then determined whether the flare variation converges or not (S5). When the flare variation converges, a dummy pattern is generated based upon the density map acquired in S2 (S8).

Instead of the above convergence judgment, it can be determined whether the flare variation is within the specified variation range.

On the other hand, when the flare variation does not converge in S5, an amount of change in flare variation (f′(x)) is calculated for each mesh (S6). Next, the density map that makes the amount of flare variation zero is calculated (S7), on the assumption that the density and the flare variation amount have a linear relation, and then, the process returns to S3. The density map that makes the amount of flare variation zero may be calculated only for the mesh where the dummy pattern can be arranged. The processes in S3 to S7 are repeated until the flare variation converges. After the flare variation converges, the dummy pattern is generated based upon the density map acquired in S7 (S8).

### Second Embodiment

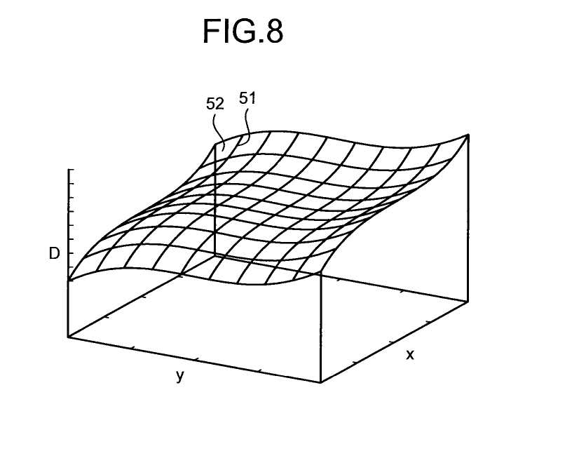

FIG. 8 is a view illustrating an approximating method of a density map according to a second embodiment.

In FIG. 8, a density D corresponding to coverage of a mask pattern is expressed by a polynomial equation with x and y on an xy plane as variables. For example, D=a*x³+b*y³ can be derived. a and b are coefficients of the polynomial equation.

When the density map that makes the amount flare variation zero is calculated, the coefficients a and b of the polynomial equation are changed, instead of changing the density D in each divided region 52 separated by the mesh 51.

With this, compared to the case where the density D is optimized by directly changing the density D for each of the divided regions 52, the number of parameters (referred to as design variables) that should be optimized can be reduced, whereby the calculation amount for optimizing the density D can be reduced. For example, when there are 100 divided regions 52, there are 100 design variables. On the other hand, when D=a*x³+b*y³, only two design variables are enough.

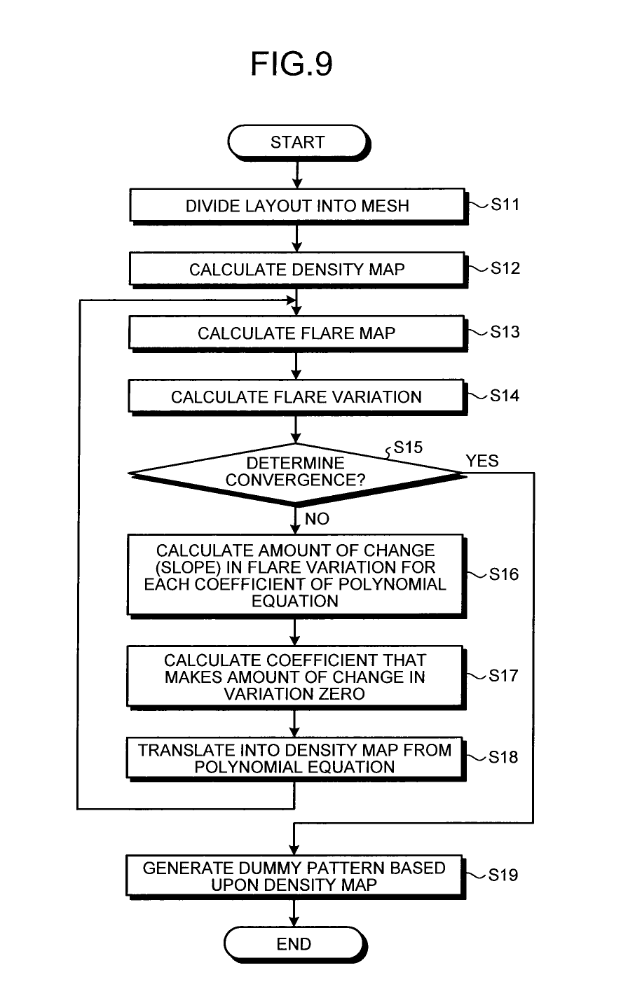

FIG. 9 is a flowchart illustrating the method of adjusting the density map for equalizing the flare distribution according to the second embodiment.

In FIG. 9, the layout region is divided like a mesh (S11). Then, a density map, a flare map, and a flare variation are calculated for each mesh (S12 to S14). The flare map and the flare variation may be calculated only in the region where the uniformity of the flare amount has to be enhanced. It is then determined whether the flare variation converges or not (S15). When the flare variation converges, a dummy pattern is generated based upon the density map acquired in S12 (S19).

Instead of the above convergence judgment, it can be determined whether the flare variation is within the specified variation range.

On the other hand, when the flare variation does not converge in S15, the amount of change in flare variation is calculated for each coefficient in the polynomial equation expressing the density distribution (S16). Next, the coefficient that makes the amount of flare variation zero is calculated (S17), and the density map is obtained from the polynomial equation (S18). Then, the process returns to S13. The processes in S13 to S18 are repeated until the flare variation converges. After the flare variation converges, the dummy pattern is generated based upon the density map acquired in S18 (S19).

In FIG. 9, the method of obtaining the density map from the polynomial equation has been described in order to realize a high-speed process. However, in order to attain higher accuracy for the density map obtained from the polynomial equation, the density may be optimized such that the density is directly changed for each of the divided regions, as described in the first embodiment, by using the density map optimized by the polynomial equation as an initial value.

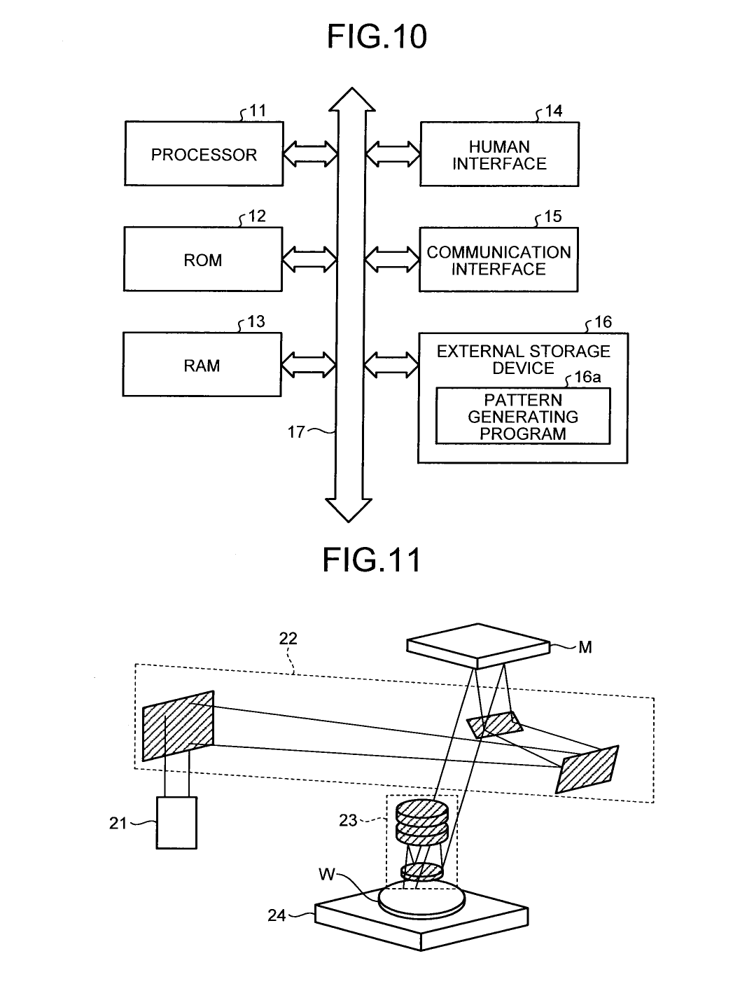

FIG. 10 is a block diagram illustrating an example of a configuration of hardware in the pattern generating device in FIG. 1.

In FIG. 10, the pattern generating device 1 can be provided with a processor 11 including a CPU, ROM 12 storing fixed data, RAM 13 that provides a work area to the processor 11, a human interface 14 that intermediates human and computer, a communication interface 15 that provides a communication way to the outside, and an external storage device 16 that stores a program for operating the processor 11 and various data, wherein the processor 11, the ROM 12, the RAM 13, the human interface 14, the communication interface 15, and the external storage device 16 are interconnected with a bus 17.

Examples of usable external storage device 16 include a magnetic disk such as hard disk, an optical disk such as DVD, and a portable semiconductor storage device such as a USB memory or memory card. Examples of usable human interface 14 include a keyboard, a mouse, and a touch panel as an input interface, as well as a display and a printer as an output interface. Examples of usable communication interface 15 include a LAN card, modem, and rooter for the connection to Internet or LAN.

A pattern generating program 16a is installed to the external storage device 16. According to the pattern generating program 16a, coverage of a mask pattern is calculated in order that the uniformity of a flare amount in an exposure region is enhanced by applying an optimization algorithm, and a dummy pattern of a mask is generated based upon the coverage.

When the pattern generating program 16a is executed by the processor 11, an amount of flare generated through the mask during an EUV exposure is evaluated for a layout pattern generated by the CAD system 2 or a layout pattern to which an optical proximity correction is performed by the OPC processing device 3. Then, the coverage of the mask pattern is calculated by employing the optimization algorithm in order to enhance the uniformity of the flare amount in the exposure region. Dummy pattern data of the mask is generated based upon the coverage of the mask pattern, and this mask pattern data is sent to the mask data creating device 4.

The pattern generating program 16a that is executed by the processor 11 may be stored in the external storage device 16, and during the execution of the program, this program may be read into the RAM 13. Alternatively, the pattern generating program 16a may be stored in the ROM 12 beforehand, or may be acquired through the communication interface 15. The pattern generating program 16a may also be executed by a stand-alone computer, or by a cloud computer.

### Third Embodiment

FIG. 11 is a perspective view illustrating a schematic configuration of an EUV exposure device to which an exposure mask according to a third embodiment is applied.

In FIG. 11, the EUV exposure device includes an EUV light source 21 that emits EUV light, an illumination optical system 22 that guides EUV light emitted from the EUV light source 21 to an exposure mask M, a projection optical system 23 that projects the EUV light reflected from the exposure mask M to a wafer W, a wafer stage 24 on which the wafer W is placed, and the exposure mask M corresponding to a layout pattern projected onto the wafer W. A dummy pattern can be added to the exposure mask M in order to equalize the amount of flare emitted on the wafer W through the exposure mask M.

The wavelength of the EUV light can be set as about 13 nm to 14 nm, for example. A mirror plate that reflects the EUV light can be used as the exposure mask M, and a mask pattern is formed by mounting a light absorbing pattern on the mirror plate. A multilayer reflection film made of Mo/Si multilayer film can be used as the mirror plate, for example. A Ta-based material can be used as the light absorbing pattern.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern generating method comprising:
evaluating an amount of flare generated through a mask during an EUV exposure;
calculating optimal coverage of a mask pattern by applying an optimization algorithm for enhancing uniformity of the amount of flare in an exposure region; and
generating a dummy pattern of the mask based upon the coverage of the mask pattern.

2. The pattern generating method according to claim 1, wherein the optimization algorithm obtains an amount of change in a variation of a flare amount when the coverage is changed for each of divided regions formed by dividing a layout region of the mask pattern, and calculates optimal coverage by a gradient method such that the variation of the flare amount becomes close to a minimum value.

3. The pattern generating method according to claim 1, wherein the optimization algorithm obtains an amount of change in a variation of a flare amount when the coverage is changed for each of divided regions formed by dividing a layout region of the mask pattern, and calculates optimal coverage by Newton method or quasi-Newton method such that the variation of the flare amount becomes close to a minimum value.

4. The pattern generating method according to claim 1, wherein the flare amount in the exposure region is evaluated by a calculation of a convolution integral between distribution of coverage obtained for each region in the mask pattern and a point spread function.

5. The pattern generating method according to claim 1, wherein the coverage is calculated only for a region where the dummy pattern can be arranged.

6. The pattern generating method according to claim 1, wherein the flare amount is evaluated only for a region where the uniformity of the flare amount is to be enhanced.

7. The pattern generating method according to claim 1, wherein coverage of the mask pattern is approximated by a polynomial equation, and a coefficient of the polynomial equation is calculated by using an optimization algorithm in order to enhance the uniformity of the flare amount in the exposure region.

8. The pattern generating method according to claim 7, wherein after the coefficient of the polynomial equation is calculated for enhancing the uniformity of the flare amount in the exposure region, an amount of change in a variation of the flare amount when the coverage is changed for each of divided regions formed by dividing a layout region of the mask pattern is obtained by using coverage distribution obtained from the coefficient as an initial value, and coverage is calculated by a gradient method in order to make the variation of the flare amount close to the minimum value.

9. A pattern forming method comprising:
performing an EUV exposure to an exposure region on a wafer through a mask that has a mask pattern to which a dummy pattern is added according to coverage of the mask pattern, the coverage being calculated by applying an optimization algorithm in order to enhance uniformity of a flare amount in the exposure region; and
forming an EUV exposure pattern on the wafer based upon the EUV exposure.

10. The pattern forming method according to claim 9, wherein the optimization algorithm obtains an amount of change in a variation of a flare amount when the coverage is changed for each of divided regions formed by dividing a layout region of the mask pattern, and calculates optimal coverage by a gradient method such that the variation of the flare amount becomes close to a minimum value.

11. The pattern forming method according to claim 9, wherein the optimization algorithm obtains an amount of change in a variation of a flare amount when the coverage is changed for each of divided regions formed by dividing a layout region of the mask pattern, and calculates optimal coverage by Newton method or quasi-Newton method such that the variation of the flare amount becomes close to a minimum value.

12. The pattern forming method according to claim 9, wherein the flare amount in the exposure region is evaluated by a calculation of a convolution integral between distribution of coverage obtained for each region in the mask pattern and a point spread function.

13. The pattern forming method according to claim 9, wherein coverage of the mask pattern is approximated by a polynomial equation, and a coefficient of the polynomial equation is calculated by using an optimization algorithm in order to enhance the uniformity of the flare amount in the exposure region.

14. The pattern forming method according to claim 13, wherein after the coefficient of the polynomial equation is calculated for enhancing the uniformity of the flare amount in the exposure region, an amount of change in a variation of the flare amount when the coverage is changed for each of divided regions formed by dividing a layout region of the mask pattern is obtained by using coverage distribution obtained from the coefficient as an initial value, and coverage is calculated by a gradient method in order to make the variation of the flare amount close to the minimum value.

15. A pattern generating program that causes a computer to execute:
evaluating an amount of flare generated through a mask during an EUV exposure;
calculating optimal coverage of a mask pattern by applying an optimization algorithm for enhancing uniformity of the amount of flare in an exposure region; and
generating a dummy pattern of the mask based upon the coverage of the mask pattern.

16. The pattern generating program according to claim 15, wherein the optimization algorithm obtains an amount of change in a variation of a flare amount when the coverage is changed for each of divided regions formed by dividing a layout region of the mask pattern, and calculates optimal coverage by a gradient method such that the variation of the flare amount becomes close to a minimum value.

17. The pattern generating program according to claim 15, wherein the optimization algorithm obtains an amount of change in a variation of a flare amount when the coverage is changed for each of divided regions formed by dividing a layout region of the mask pattern, and calculates optimal coverage by Newton method or quasi-Newton method such that the variation of the flare amount becomes close to a minimum value.

18. The pattern generating program according to claim 15, wherein the flare amount in the exposure region is evaluated by a calculation of a convolution integral between distribution of coverage obtained for each region in the mask pattern and a point spread function.

19. The pattern generating program according to claim 15, wherein coverage of the mask pattern is approximated by a polynomial equation, and a coefficient of the polynomial equation is calculated by using an optimization algorithm in order to enhance the uniformity of the flare amount in the exposure region.

20. The pattern generating program according to claim 19, wherein after the coefficient of the polynomial equation is calculated for enhancing the uniformity of the flare amount in the exposure region, an amount of change in a variation of the flare amount when the coverage is changed for each of divided regions formed by dividing a layout region of the mask pattern is obtained by using coverage distribution obtained by the coefficient as an initial value, and coverage is calculated by a gradient method in order to make the variation of the flare amount close to the minimum value.
